(19) United States
(12) Patent Application Publication
(10) Pub. No.: US 2004/0069991 A1
(43) Pub. Date: Apr. 15, 2004

(54) Perovskite cuprate electronic device structure and process

(75) Inventors: Gregory Dunn, Arlington Heights, IL (US); Robert Croswell, Hanover Park, IL (US); Jeffrey Petsinger, Wayne, IL (US)

Correspondence Address: OBLON SPIVAK MCCLELLAND MAIER & NEUSTADT, 1755 JEFFERSON DAVIS HIGHWAY, FOURTH FLOOR, ARLINGTON, VA, 22202, US

(73) Assignee: MOTOROLA, INC., Schaumburg, IL

(21) Appl. No.: 10/267,692

(22) Filed: Oct. 10, 2002

(51) Int. Cl. H01L 29/04

(52) U.S. Cl. 257/75

(57) ABSTRACT

High quality epitaxial layers of monocrystalline materials (26) can be grown overlying monocrystalline substrates (22) such as large silicon wafers by forming a compliant substrate for growing the monocrystalline layers. An accommodating buffer layer (24) comprises a layer of monocrystalline oxide spaced apart from a silicon wafer by an amorphous interface layer (28) of silicon oxide. The amorphous interface layer dissipates strain and permits the growth of a high quality monocrystalline oxide accommodating buffer layer. Any lattice mismatch between the accommodating buffer layer and the underlying silicon substrate is taken care of by the amorphous interface layer. Some preferred electronic devices are described that use a layer or pattern of a perovskite cuprate (2125, 2305, 2310, 2315, 2405) such as YBa₂Cu₃O_{7-y}(YBCO) or Y₁₋ₓPrₓBa₂Cu₃O_{7-y}(YPBCO, 0<x<1) over a buffer layer (2120) of lanthanum strontium aluminum tantalate (LSAT).

### FIELD OF THE INVENTION

This invention relates generally to electronic structures and devices and to a method for their fabrication, and more specifically to semiconductor structures and devices and to the fabrication and use of semiconductor structures, devices, and integrated circuits that include a monocrystalline material layer comprised of semiconductor material, compound semiconductor material, and/or other types of material such as metals and non-metals.

### BACKGROUND OF THE INVENTION

A candidate technology for sub-50 nm channel length transistors is the Mott field-effect transistor, under investigation at IBM Watson Research Center. U.S. Pat. No. 6,333,543 describes such a device fabricated on a strontium titatanate (STO) single crystal substrate. A Mott insulator perovskite oxide such as the cuprates La₂CuO₄ or Y₍₁₋ₓ₎Pr₍ₓ₎Ba₂Cu₃O₇(YBCO) is used for p-type channel layers, and the perovskite cuprate Nd₂CuO₄ is used for n-type channel layers. A perovskite oxide such as STO is used as the gate oxide. Under an applied gate field, the Mott insulator becomes conducting. The Mott FET has a basic structure and function that is similar to a MOSFET, but the device dimensions are limited only by the methods available for patterning, and scaling to below 30 nm is possible.

The Mott FET faces two fundamental barriers to practical implementation. First, the use of very high cost STO substrates, which are available only in very small diameters (2 inches), imposes a severe limit on manufacturability and cost competitiveness. Second, the performance of the Mott FET is strongly dependent on the epitaxial quality of the channel layer. The highest degree of long range order and the lowest density of imperfections is required. Lattice mismatch (>2.5%) when STO is used under a cuprate such as YBCO will result in strain in the YBCO layer, causing defects to form and thus degrading device performance.

Planar microstrip high temperature superconductor circuits such as resonators, filters, and phase-shifting circuits are related to Mott transistors by benefiting from the use of a high quality epitaxial layer of a cuprate. Such planar microstrip high temperature superconductor circuits are very attractive for high performance, low noise, low insertion loss communication systems, because they offer lower conductor losses compared to conventional conductors. Quality factors in the tens of thousands have been reported. Highly selective bandpass filters with steep skirts, insertion loss under 0.3 dB, and 60 dB out of band rejection (at 5 MHz for a 1.8 GHz center frequency) have been demonstrated and are candidate receive filters for base transceiver stations of future mobile communication systems such as UMTS that will face strong interference problems. Combining high temperature superconductors with tunable dielectrics (i.e., dielectrics with field-dependent permittivity) such as strontium titanate (STO) or barium strontium titanate (BSTO) would allow high performance, tunable microwave devices.

A manufacturing challenge for high temperature superconductors is the need for an inexpensive, large format, single crystal substrate that is chemically compatible with and lattice-matched to superconducting YBa₂Cu₃O₇(YBCO) or Y₁₋PrₓBa₂Cu₃O_{7-y}(YPBCO, 0<x<1). STO or BSTO is not an ideal material to use to achieve good lattice matching with high temperature superconducting materials such as YBCO and YPBCO. Lanthanum aluminate (LAO) is a widely-used material on which to grow YBCO layers. Although LAO may be acceptable in some situations, it presents several disadvantages. Its lattice constant, 3.80 A, is 1.7% mismatched to YBCO (3.85 A); the stress induced can be a problem for the brittle superconductor material. LAO is also susceptible to twinning, which can corrupt the crystallinity of the overlying YBCO upon cooling after growth. Finally, LAO is 3.3% lattice-mismatched to STO or BSTO, which makes the epitaxial growth of high quality tunable superconductor devices more difficult.

Accordingly, a need exists for a semiconductor structure that provides a thin, high quality monocrystalline film or layer that is closely lattice matched with cuprates such as YBCO and YPBCO and can be grown over a large, low cost monocrystalline substrate, and for a process for making such a structure. In other words, there is a need for providing the formation of a monocrystalline substrate that is compliant with a high quality monocrystalline cuprate layer so that true two-dimensional growth can be achieved for the formation of quality semiconductor, superconductor, and metal-insulator transition structures, devices and integrated circuits.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13 and 14 illustrate schematically, in cross section, device structures that can be used in accordance with various embodiments of the invention;

FIGS. 15-19 include illustrations of cross-sectional views of a portion of an integrated circuit that includes a compound semiconductor portion, a bipolar portion, and a MOS portion in accordance with what is shown herein;

FIG. 20 shows a cross section diagram of the structure of a Mott field effect transistor (FET), in accordance with one embodiment of the present invention. FIGS. 21-24 show examples of high temperature superconducting devices that benefit by the use of lanthanum strontium aluminum titanate under the YBCO or YPBCO layer, in accordance with embodiments of the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

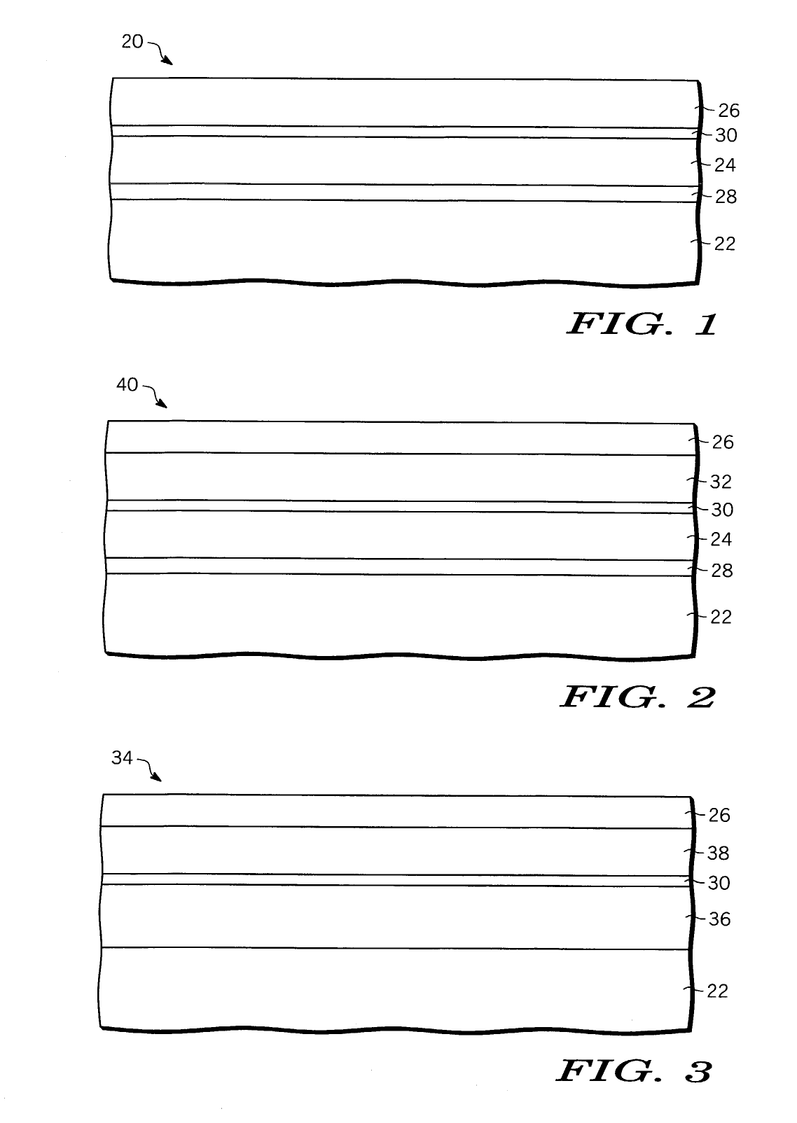

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Substrate 22 may also be, for example, silicon-oninsulator (SOI), where a thin layer of silicon is on top of an insulating material such as silicon oxide or glass. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and other perovskite oxide materials, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxides or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II (A or B) and VIA elements (II-VI semiconductor compounds), mixed II-VI compounds, Group IV and VI elements (IV-VI semiconductor compounds), mixed IV-VI compounds, Group IV elements (Group IV semiconductors), and mixed Group IV compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe), silicon (Si), germanium (Ge), silicon germanium (SiGe), silicon germanium carbide (SiGeC), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer 32 is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer may then be optionally exposed to an anneal process to convert at least a portion of the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides strain relief for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming at least a portion of a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV, monocrystalline compound semiconductor materials, or other monocrystalline materials including oxides and nitrides.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate typically (100) oriented. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The lattice structure of the resulting crystalline oxide exhibits a substantially 45 degree rotation with respect to the substrate silicon lattice structure. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by depositing a surfactant layer comprising one element of the compound semiconductor layer to react with the surface of the oxide layer that has been previously capped. The capping layer is preferably up to 3 monolayers of Sr—O, Ti—O, strontium or titanium. The template layer is preferably of Sr—Ga, Ti—Ga, Ti—As, Ti—O—As, Ti—O—Ga, Sr—O—As, Sr—Ga—O, Sr—Al—O, or Sr—Al. The thickness of the template layer is preferably about 0.5 to about 10 monolayers, and preferably about 0.5-3 monolayers. By way of a preferred example 0.5-3 monolayers of Ga deposited on a capped Sr—O terminated surface have been illustrated to successfully grow GaAs layers. The resulting lattice structure of the compound semiconductor material exhibits a substantially 45 degree rotation with respect to the accommodating buffer layer lattice structure.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 4 nm to ensure adequate crystalline and surface quality and is formed of monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a substantially 45 degree rotation with respect to the substrate silicon lattice structure.

An accommodating buffer layer formed of these zirconate or hafnate materials is suitable for the growth of a monocrystalline material layer which comprises compound semiconductor materials in an indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is about 0.5-10 monolayers of one of a material M—N and a material M—O—N, wherein M is selected from at least one of Zr, Hf, Ti, Sr, and Ba; and N is selected from at least one of As, P, Ga, Al, and In.

Alternatively, the template may comprise 0.5-10 monolayers of gallium (Ga), aluminum (Al), indium (In), or a combination of gallium, aluminum or indium, zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 0.5-2 monolayers of one of these materials. By way of an example, for a barium zirconate accommodating buffer layer, the surface is terminated with 0.5-2 monolayers of zirconium followed by deposition of 0.5-2 monolayers of arsenic to form a Zr—As template. A monocrystalline layer of the compound semiconductor material from the indium phosphide system is then grown on the template layer. The resulting lattice structure of the compound semiconductor material exhibits a substantially 45 degree rotation with respect to the accommodating buffer layer lattice structure and a lattice mismatch between the buffer layer and (100) oriented InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 3-10 nm. The lattice structure of the resulting crystalline oxide exhibits a substantially 45 degree rotation with respect to the substrate silicon lattice structure. Where the monocrystalline layer comprises a compound semiconductor material, the II-VI compound semiconductor material can be, for example, zinc selenide (ZnSe) or zinc sulfur selenide (ZnSSe). A suitable template for this material system includes 0.5-10 monolayers of zinc-oxygen (Zn—O) followed by 0.5-2 monolayers of an excess of zinc followed by the selenidation of zinc on the surface. Alternatively, a template can be, for example, 0.5-10 monolayers of strontiumsulfur (Sr—S) followed by the ZnSSe.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a substantial (i.e., effective) match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The superlattice period can have a thickness of about 2-15 nm, preferably 2-10 nm. The template for this structure can be the same as that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about 0.5-2 monolayers can be used as a nucleating site for the subsequent growth of the monocrystalline material layer which in this example is a compound semiconductor material. The formation of the oxide layer is capped with either a 0.5-2 monolayer of strontium or a 0.5-2 monolayer of titanium to act as a nucleating site for the subsequent deposition of the monocrystalline germanium. The layer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0% at the monocrystalline material layer 26 to about 50% at the accommodating buffer layer 24. The additional buffer layer 32 preferably has a thickness of about 10-30 nm. Varying the composition of the buffer layer from GaAs to InGaAs serves to provide an effective (i.e. substantial) lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 1 nm to about 100 nm, preferably about 1-10 nm, and more preferably about 3-5 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 nm to about 500 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation; In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

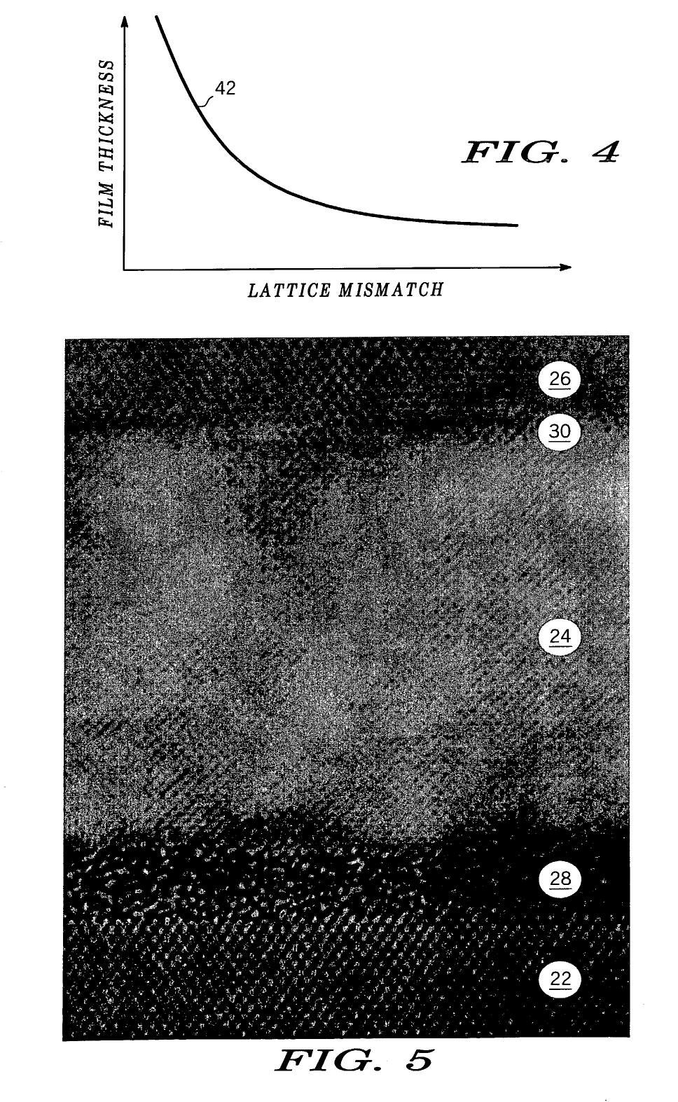

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is typically a (100) oriented monocrystalline silicon wafer and accommodating buffer layer 24 is a layer of strontium barium titanate. Substantial (i.e., effective) matching of lattice constants between these two materials is achieved by rotating the crystal orientation of the titanate material by approximately 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by substantially 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by substantially 45° with respect to the host oxide crystal. In some instances, a crystalline semiconductor buffer layer 32 between the host oxide and the grown monocrystalline material layer 26 can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is oriented on axis or, at most, about 6° off axis, and preferably misoriented 1-3° off axis toward the [110] direction. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer (preferably 1-3 monolayers) of strontium, barium, a combination of strontium and barium, or other alkaline earth metals or combinations of alkaline earth metals in an MBE apparatus. In the case where strontium is used, the substrate is then heated to a temperature above 720° C. as measured by an optical pyrometer to cause the strontium to react with the native silicon oxide layer. The strontium serves to reduce the silicon oxide to leave a silicon oxide-free surface. The resultant surface may exhibit an ordered (2×1) structure. If an ordered (2×1) structure has not been achieved at this stage of the process, the structure may be exposed to additional strontium until an ordered (2×1) structure is obtained. The ordered (2×1) structure forms a template for the ordered growth of an overlying layer of a monocrystalline oxide. The template provides the necessary chemical and physical properties to nucleate the crystalline growth of an overlying layer.

It is understood that precise measurement of actual temperatures in MBE equipment, as well as other processing equipment, is difficult, and is commonly accomplished by the use of a pyrometer or by means of a thermocouple placed in close proximity to the substrate. Calibrations can be performed to correlate the pyrometer temperature reading to that of the thermocouple. However, neither temperature reading is necessarily a precise indication of actual substrate temperature. Furthermore, variations may exist when measuring temperatures from one MBE system to another MBE system. For the purpose of this description, typical pyrometer temperatures will be used, and it should be understood that variations may exist in practice due to these measurement difficulties.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of above 720° C. At this temperature a solid state reaction takes place between the strontium oxide and the native silicon oxide causing the reduction of the native silicon oxide and leaving an ordered (2×1) structure on the substrate surface. If an ordered (2×1) structure has not been achieved at this stage of the process, the structure may be exposed to additional strontium until an ordered (2×1) structure is obtained. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-600° C., preferably 350°-550° C., and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.1-0.8 nm per minute, preferably 0.3-0.5 nm per minute. After initiating growth of the strontium titanate, the partial pressure of oxygen is increased above the initial minimum value. The stoichiometry of the titanium can be controlled during growth by monitoring RHEED patterns and adjusting the titanium flux. The overpressure of oxygen causes the growth of an amorphous silicon oxide layer at the interface between the underlying substrate and the strontium titanate layer. This step may be applied either during or after the growth of the strontium titanate layer. The growth of the amorphous silicon oxide layer results from the diffusion of oxygen through the strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with up to 2 monolayers of titanium, up to 2 monolayers of strontium, up to 2 monolayers of titanium-oxygen or with up to 2 monolayers of strontium-oxygen. Following the formation of this capping layer, arsenic is deposited to form a Ti—As bond, a Ti—O—As bond or a Sr—O—As bond. Any of these form an appropriate template for deposition and formation of a gallium arsenide monocrystalline layer. Following the formation of the template, gallium is subsequently introduced to the reaction with the arsenic and gallium arsenide forms. Alternatively, 0.5-3 monolayers of gallium can be deposited on the capping layer to form a Sr—O—Ga bond, or a Ti—O—Ga bond, and arsenic is subsequently introduced with the gallium to form the GaAs.

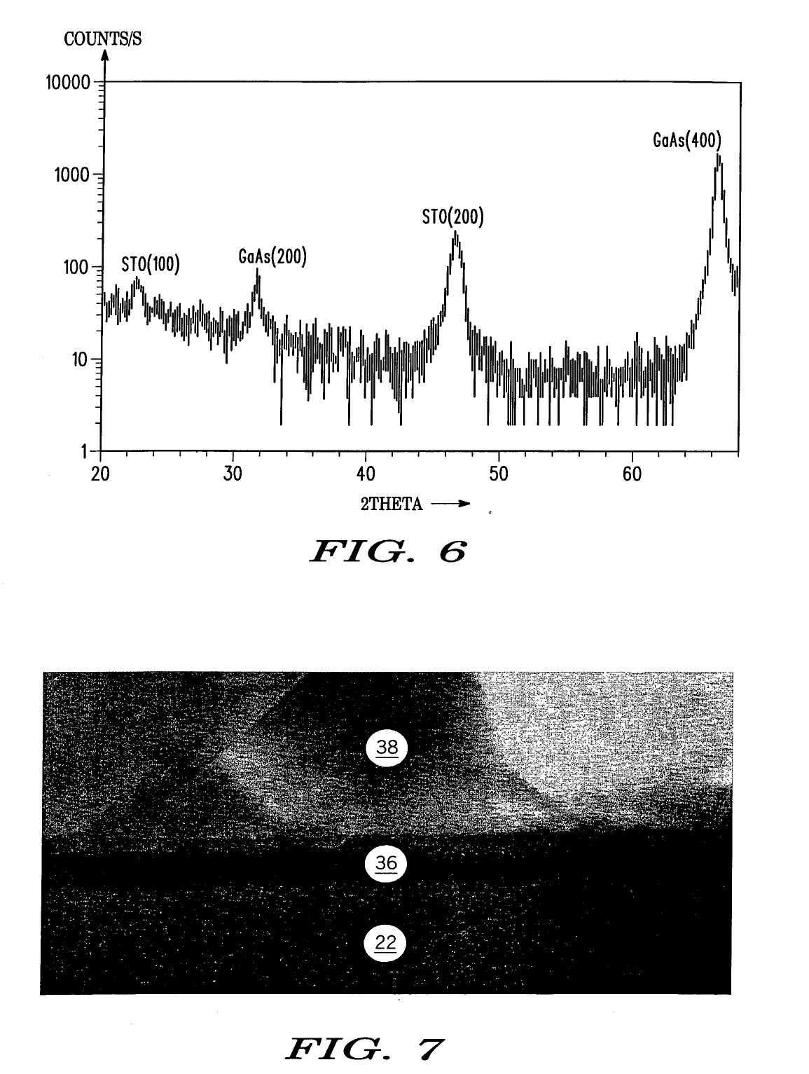

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed, which relieves strain due to lattice mismatch. GaAs compound semiconductor layer 26 was then grown epitaxially using template layer 30.

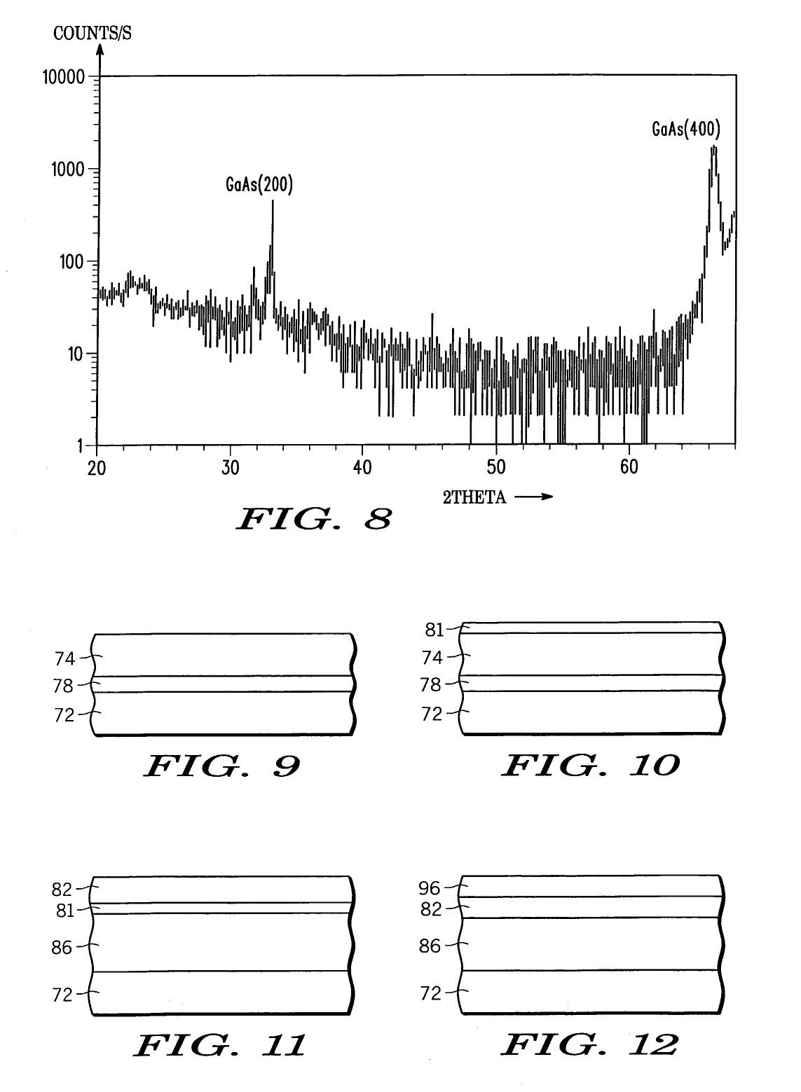

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) oriented.

The structure illustrated in FIG. 2 can be formed by the process discussed above with the addition of an additional buffer layer deposition step. The additional buffer layer 32 is formed overlying the template layer 30 before the deposition of the monocrystalline material layer 26. If the additional buffer layer 32 is a monocrystalline material comprising a compound semiconductor superlattice, such a superlattice can be deposited, by MBE for example, on the template 30 described above. If instead, the additional buffer layer is a monocrystalline material layer comprising a layer of germanium, the process above is modified to cap the first buffer layer of strontium titanate with a final template layer of either strontium or titanium and then by depositing germanium to react with the strontium or titanium. The germanium buffer layer can then be deposited directly on this template.

Structure 34, illustrated in FIG. 3, may be formed by growing an accommodating buffer layer 24, forming an amorphous oxide layer 28 over substrate 22, and growing semiconductor layer 38 over the accommodating buffer layer, as described above. The accommodating buffer layer 24 and the amorphous oxide layer 28 are then exposed to a higher temperature anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer 24, the amorphous oxide layer 28, and monocrystalline layer 38 to a rapid thermal anneal process with a peak temperature of about 700° C. to about 1000° C. (actual temperature) and a process time of about 5 seconds to about 20 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 38 may be required to prevent degradation of layer 38 during the anneal process. For example, when layer 38 includes GaAs, the anneal environment preferably includes an overpressure of arsenic to mitigate degradation of layer 38. Alternately, an appropriate anneal cap, such as silicon nitride, may be utilized to prevent the degradation of layer 38 during the anneal process with the anneal cap being removed after the annealing process.

As noted above, layer 38 of structure 34 may include any materials suitable for either of layers 32 or 26. Accordingly, any deposition or growth methods described in connection with either layer 32 or 26 may be employed to deposit layer 38.

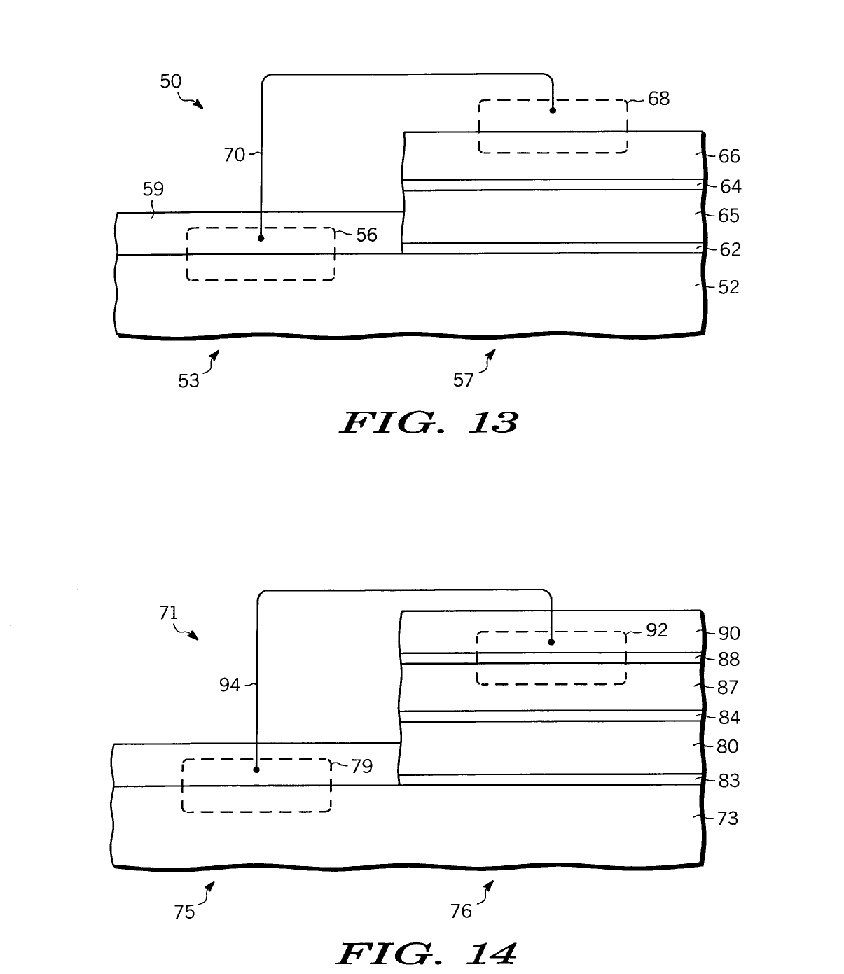

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

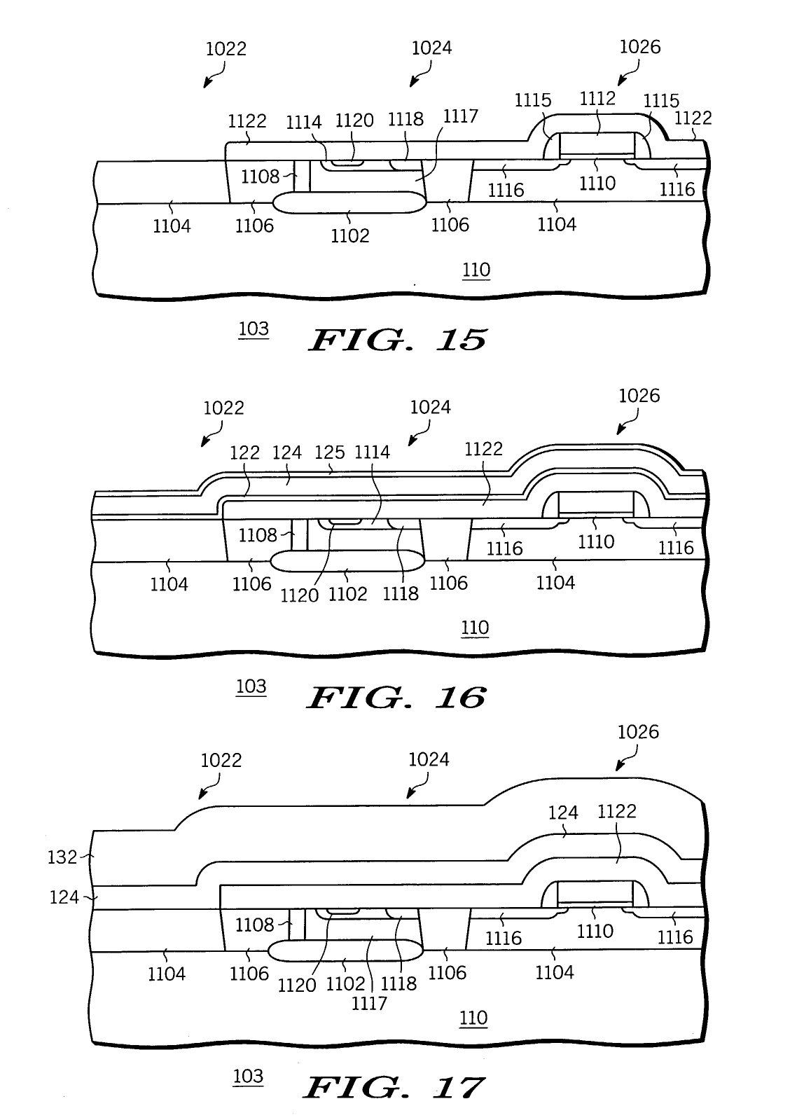

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) oriented and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, niobates, alkaline earth metal tin-based perovskites, lanthanum aluminate, lanthanum scandium oxide, and gadolinium oxide can also be grown. Further, by a similar process such as MBE, other monocrystalline material layers comprising other III-V, II-VI, and IV-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide, respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen, and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

Single crystal silicon has 4-fold symmetry. That is, its structure is essentially the same as it is rotated in 90 degree steps in the plane of the (100) surface. Likewise, strontium titanate and many other oxides have a 4-fold symmetry. On the other hand, GaAs and related compound semiconductors have a 2-fold symmetry. The 0 degree and 180 degree rotations of the 2-fold symmetry are not the same as the 90 degree and 270 degree rotations of the 4-fold symmetry. If GaAs is nucleated upon strontium titanate at multiple locations on the surface, two different phases are produced. As the material continues to grow, the two phases meet and form anti-phase domains. These anti-phase domains can have an adverse effect upon certain types of devices, particularly minority carrier devices like lasers and light emitting diodes.

In accordance with one embodiment of the present invention, in order to provide for the formation of high quality monocrystalline compound semiconductor material, the starting substrate is off-cut or misoriented from the ideal (100) orientation by 0.5 to 6 degrees in any direction, and preferably 1 to 2 degrees toward the [110] direction. This offcut provides for steps or terraces on the silicon surface and it is believed that these substantially reduce the number of anti-phase domains in the compound semiconductor material, in comparison to a substrate having an offcut near 0 degrees or off cuts larger than 6 degrees. The greater the amount of off-cut, the closer the steps and the smaller the terrace widths become. At very small angles, nucleation occurs at other than the step edges, decreasing the size of single phase domains. At high angles, smaller terraces decrease the size of single phase domains. Growing a high quality oxide, such as strontium titanate, upon a silicon surface causes surface features to be replicated on the surface of the oxide. The step and terrace surface features are replicated on the surface of the oxide, thus preserving directional cues for subsequent growth of compound semiconductor material. Because the formation of the amorphous interface layer occurs after the nucleation of the oxide has begun, the formation of the amorphous interface layer does not disturb the step structure of the oxide.

After the growth of an appropriate accommodating buffer layer, such as strontium titanate or other materials as described earlier, a template layer is used to promote the proper nucleation of compound semiconductor material. In accordance with one embodiment, the strontium titanate is capped with up to 2 monolayers of SrO. The template layer 30 for the nucleation of GaAs is formed by raising the substrate to a temperature in the range of 540 to 630 degrees and exposing the surface to gallium. The amount of gallium exposure is preferably in the range of 0.5 to 5 monolayers. It is understood that the exposure to gallium does not imply that all of the material will actually adhere to the surface. Not wishing to be bound by theory, it is believed that the gallium atoms adhere more readily at the exposed step edges of the oxide surface. Thus, subsequent growth of gallium arsenide preferentially forms along the step edges and prefer an initial alignment in a direction parallel to the step edge, thus forming predominantly single domain material. Other materials besides gallium may also be utilized in a similar fashion, such as aluminum and indium or a combination thereof.

After the deposition of the template, a compound semiconductor material such as gallium arsenide may be deposited. The arsenic source shutter is preferably opened prior to opening the shutter of the gallium source. Small amounts of other elements may also be deposited simultaneously to aid nucleation of the compound semiconductor material layer. For example, aluminum may be deposited to form AlGaAs. As noted above, layer 38, illustrated in FIG. 3, comprises a monocrystalline material that can be grown epitaxially over a monocrystalline oxide material, such as material used to form accommodating buffer layer 24. In accordance with one embodiment of the invention, layer 38 includes materials different from those used to form layer 26. For example, in a preferred embodiment, layer 38 includes AlGaAs, which is deposited as a nucleation layer at a relatively slow growth rate. For example, the growth rate of layer 38 of AlGaAs can be approximately 0.10-0.5 μm/hr. In this case, growth can be initiated by first depositing As on template layer 30, followed by deposition of aluminum and gallium. Deposition of the nucleation layer generally is accomplished at about 300-600° C., and preferably 400-500° C. In accordance with one exemplary embodiment of the invention, the nucleation layer is about 1 nm to about 500 nm thick, and preferably 5 nm to about 50 nm. In this case, the aluminum source shutter is preferably opened prior to opening the gallium source shutter. The amount of aluminum is preferably in the range from 0 to 50% (expressed as a percentage of the aluminum content in the AlGaAs layer), and is most preferably about 15-25%. Other materials, such as InGaAs, could also be used in a similar fashion. Once the growth of compound semiconductor material is initiated, other mixtures of compound semiconductor materials can be grown with various compositions and various thicknesses as required for various applications. For example, a thicker layer of GaAs may be grown on top of the AlGaAs layer to provide a semi-insulating buffer layer prior to the formation of device layers.

The quality of the compound semiconductor material can be improved by including one or more in-situ anneals at various points during the growth. The growth is interrupted, and the substrate is raised to a temperature of between 500°-650° C., and preferably about 550°-600° C. The anneal time depends on the temperature selected, but for an anneal of about 550° C., the length of time is preferably about 15 minutes. The anneal can be performed at any point during the deposition of the compound semiconductor material, but preferably is performed when there is 50 nm to 500 nm of compound semiconductor material deposited. Additional anneals may also be done, depending on the total thickness of material being deposited.

In accordance with one embodiment, monocrystalline material layer 26 is GaAs. Layer 26 may be deposited on layer 24 at various rates, which may vary from application to application; however in a preferred embodiment, the growth rate of layer 26 is about 0.2 to 1.0 μm/hr. The temperature at which layer 26 is grown may also vary, but in one embodiment, layer 26 is grown at a temperature of about 300°-600° C. and preferably about 350°-500° C.

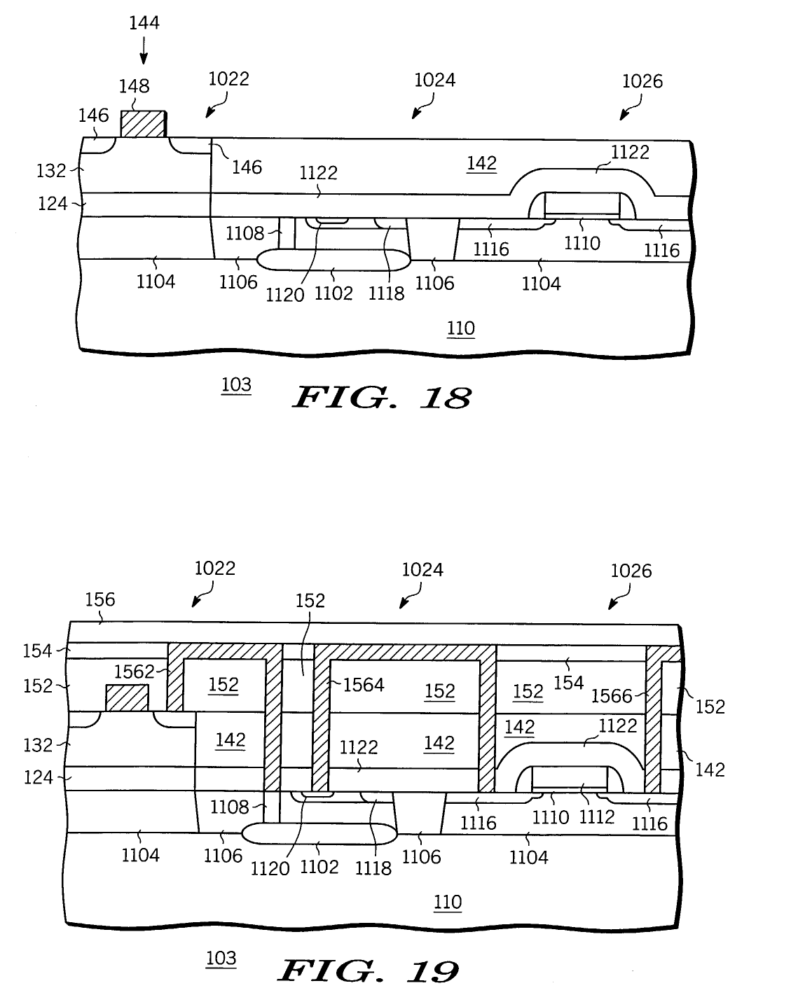

Turning now to FIGS. 9-12, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 9. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, or the like as illustrated in FIG. 10 with a thickness of a few tens of nanometers but preferably with a thickness of about 5 nm. Monocrystalline oxide layer 74 preferably has a thickness of about 2 to 10 nm.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 11. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, as shown in FIG. 12, a compound semiconductor layer 96, such as gallium nitride (GaN), is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature and high power RF applications and optoelectronics. GaN systems have particular use in the photonic industry for the blue/green and UV light sources and detection. High brightness light emitting diodes (LEDs) and lasers may also be formed within the GaN system.

Clearly, those embodiments specifically describing structures having compound semiconductor portions and Group IV semiconductor portions are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials, as well as other material layers that are used to form those devices, with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, the relatively inexpensive “handle” wafer overcomes the fragile nature of wafers fabricated of monocrystalline compound semiconductor or other monocrystalline material by placing the materials over a relatively more durable and easy to fabricate base substrate. Therefore, an integrated circuit can be formed such that all electrical components, and particularly all active electronic devices, can be formed within or using the monocrystalline material layer even though the substrate itself may include a different monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g., conventional compound semiconductor wafers).

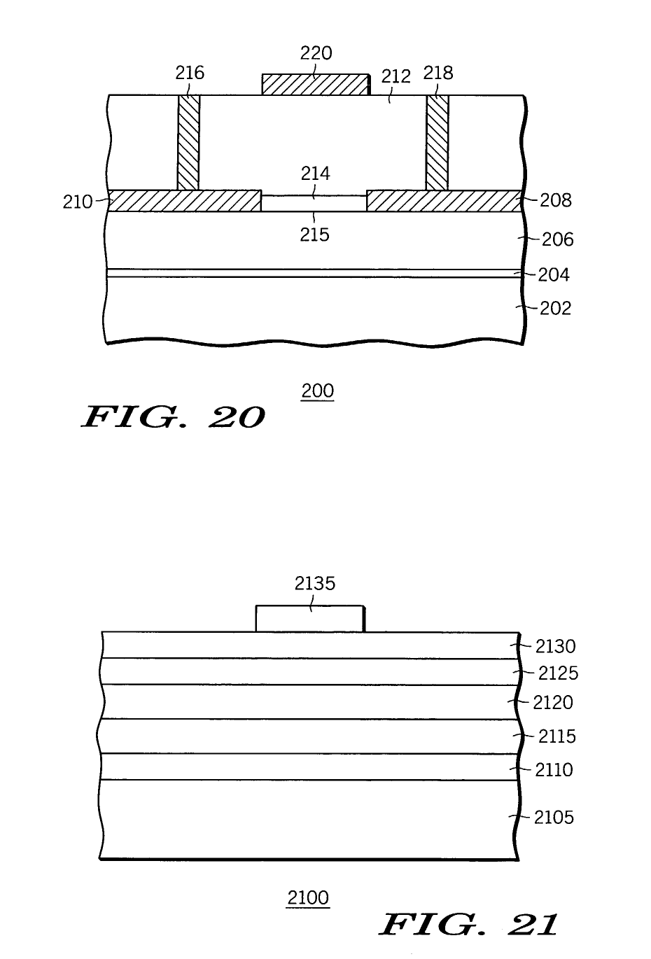

FIG. 13 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. A semiconductor component generally indicated by the dashed line 56 is formed, at least partially, in region 53. Semiconductor component 56 can be a resistor, a capacitor, an active electrical component such as a diode or a transistor, an optoelectric component such as a photo detector, or an integrated circuit such as a CMOS integrated circuit. For example, semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie semiconductor component 56.

Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer (preferably 1-3 monolayers) of strontium or strontium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including strontium, titanium and oxygen are deposited onto the template layer to form the monocrystalline oxide layer. Initially during the deposition the partial pressure of oxygen is kept near the minimum necessary to fully react with the strontium and titanium to form a monocrystalline strontium titanate layer. The partial pressure of oxygen is then increased to provide an overpressure of oxygen and to allow oxygen to diffuse through the growing monocrystalline oxide layer. The oxygen diffusing through the strontium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a capping layer 64, which can be up to 3 monolayers of titanium, strontium, strontium and oxygen, or titanium and oxygen. A layer 66 of a monocrystalline compound semiconductor material is then deposited overlying capping layer 64 by a process of molecular beam epitaxy. The deposition of layer 66 is initiated by depositing a layer of gallium onto capping layer 64. This initial step is followed by depositing arsenic and gallium to form monocrystalline gallium arsenide 66. Alternatively, barium or a mix of barium and strontium can be substituted for strontium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, pseudomorphic high electron mobility transistor (PHEMT), or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a strontium (or barium) titanate layer 65 and a gallium arsenide layer 66, similar devices can be fabricated using other substrates, monocrystalline oxide layers and other compound semiconductor layers as described elsewhere in this disclosure.

FIG. 14 illustrates a semiconductor structure 71 in accordance with a further embodiment. Structure 71 includes a monocrystalline semiconductor substrate 73 such as a monocrystalline silicon wafer that includes a region 75 and a region 76. A semiconductor component schematically illustrated by the dashed line 79 is formed in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 87 and 90 is formed from a compound semiconductor material. Layers 80 and 83 may be subject to an annealing process as described above in connection with FIG. 3 to form a single amorphous accommodating layer.

A semiconductor component generally indicated by a dashed line 92 is formed at least partially in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

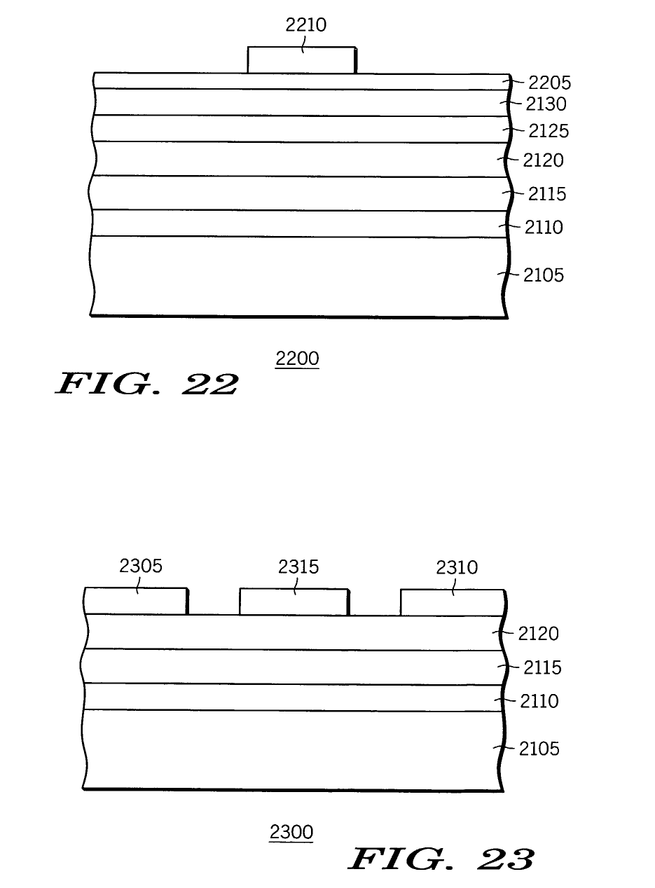

Attention is now directed to a method for forming exemplary portions of illustrative composite semiconductor structures or composite integrated circuits like 50 or 71. In particular, the illustrative composite semiconductor structure or integrated circuit 103 shown in FIGS. 15-19 includes a compound semiconductor portion 1022, a bipolar portion 1024, and a MOS portion 1026. In FIG. 15, a p-type doped, monocrystalline silicon substrate 110 is provided having a compound semiconductor portion 1022, a bipolar portion 1024, and a MOS portion 1026. Within bipolar portion 1024, the monocrystalline silicon substrate 110 is doped to form an N⁺ buried region 1102. A lightly p-type doped epitaxial monocrystalline silicon layer 1104 is then formed over the buried region 1102 and the substrate 110. A doping step is then performed to create a lightly n-type doped drift region 1117 above the N⁺ buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N⁺ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and an N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided in the manner set forth above for the subsequent processing of this portion, for example in the manner set forth below.

An accommodating buffer layer 124 is then formed over the substrate 110 as illustrated in FIG. 16. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 3-10 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 0.5-5 nm. In one particular embodiment, the thickness is 1-2 nm. Following the formation of the accommodating buffer layer 124 and the amorphous intermediate layer 122, a capping layer of up to 3 monolayers of titanium, strontium, titanium oxygen, or strontium oxygen is formed. Template layer 125 is then formed by depositing 0.5-10 monolayers of gallium, indium, aluminum, or a combination thereof and has a thickness in a range of approximately one half to ten monolayers. In one particular embodiment, the template includes gallium, titanium-arsenic, titanium-oxygen-arsenic, strontium-oxygen-arsenic, or other similar materials as previously described with respect to FIGS. 1-5. A monocrystalline compound semiconductor layer 132 is then epitaxially grown overlying the monocrystalline portion of accommodating buffer layer 124 as shown in FIG. 17. The portion of layer 132 that is grown over portions of layer 124 that are not monocrystalline may be polycrystalline or amorphous. The compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers may be formed above layer 132.

In the particular embodiment of FIG. 17, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing.

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 18. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N⁺) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

Processing continues to form a substantially completed integrated circuit 103 as illustrated in FIG. 19. An insulating layer 152 is formed over the substrate 110. The insulating layer 152 may include an etch-stop or polish-stop region that is not illustrated in FIG. 19. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 19, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the figures. Further, additional insulating layers and interconnects may be formed as necessary to form the proper interconnections between the various components within the integrated circuit 103.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

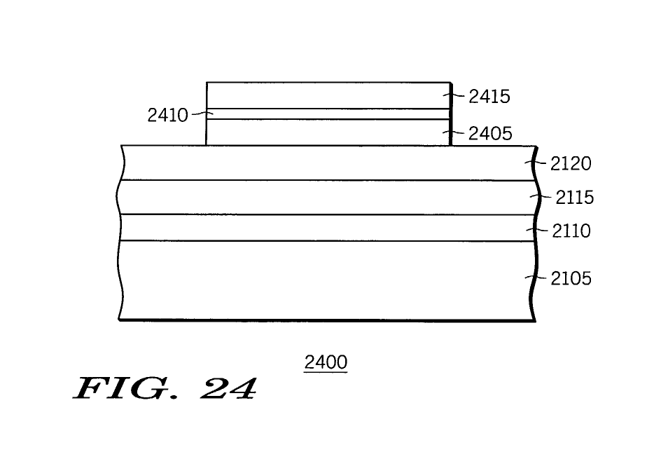

For devices that benefit from the use of perovskite cuprates such as YBa₂Cu₃O₇(YBCO) and Y₍₁₋ₓ₎Pr₍ₓ₎Ba₂Cu₃O₇(YPBCO)—for example, Mott transistors and planar microstrip high temperature superconductor circuits—a unique combination of material layers fabricated using the methods described above provides exceptional performance. In particular, lanthanum strontium aluminum tantalate (LSAT), which is a solid solution of 30 mole % LaAlO₃ and 70 mole % Sr₂AlTaO₆, is closely lattice matched to YBCO, YPBCO, and silicon, and therefore is an excellent material to use between a silicon substrate and a layer of YBCO or YPBCO. Referring to FIG. 20, a cross section diagram of the structure of a Mott field effect transistor (FET) is shown in accordance with one embodiment of the present invention. In the illustrated embodiment, the FET 200 comprises a metal-insulator transition (MIT) channel layer 214 provided between a source electrode 210 and a drain electrode 208, all of which are formed on a stack comprising accommodating buffer layer 206, amorphous interface layer 204, and monocrystalline substrate 202. A gate electrode 220 is provided on gate insulator 212, and suitable source and drain contacts 216 and 218 are formed to provide electrical connections to source electrode 210 and drain electrode 208 respectively.

In general, FET 200 operates similar to conventional FETs. When a suitable gate bias is applied to gate electrode 220 (e.g., above a characteristic threshold voltage), a channel is formed within MIT channel layer 214, allowing current flow between source electrode 210 and drain electrode 208. Because of the nature of the Mott metal-insulator transition, the channel is generally formed along the top interface of MIT channel layer 214 (i.e., the interface between layers 214 and 212). Generally, the carrier concentration and mobility of MIT channel layer 214 is modulated by application of a gate bias. Carriers are drawn into the channel electrostatically from the source and drain electrodes by application of gate bias, forming a thin conductive sheet at the interface between the channel material and the gate oxide. That is, a metal-insulator transition is not induced chemically (by introduction of dopants); rather, an insulating material is provided and carriers required to make the material conducting are introduced through application of a gate bias. As a result, this class of devices does not have an intrinsic scaling limit and can therefore operate at extremely short (e.g., about 10 nm) channel lengths.

Processing starts with preparation of substrate 202. As mentioned above, substrate 202 is a monocrystalline semiconductor or compound semiconductor wafer, preferably of large diameter. The wafer may comprise, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline (100) silicon wafer as traditionally used in the semiconductor industry.

After preparation of substrate 202, amorphous interface layer 204 is suitably formed as described above in conjunction with FIGS. 1-3. In accordance with one embodiment of the invention, amorphous interface layer 204 is grown on substrate 202 at the interface between substrate 202 and the growing accommodating buffer layer 206 by the oxidation of substrate 202 during the growth of layer 206. As described in detail above, the amorphous interface layer 204 serves to relieve strain that might otherwise occur in the monocrystalline accommodating buffer layer 206 as a result of differences in the lattice constants of the substrate 202 and the buffer layer 206.

Meanwhile, accommodating buffer layer 206 is suitably formed on amorphous interface layer 204 using any of the methods described in detail above. In accordance with one embodiment, accommodating buffer layer 206 comprises lanthanum strontium aluminum tantalate (LSAT), which is a solid solution of 30 mole % LaAlO₃ and 70 mole % Sr₂AlTaO₆ Accommodation layer 206 can be formed by a variety of growth techniques such as MBE, PLD, CSD, CVD, PVD and the like, or a combination of these deposition methods, can also be used In an alternative embodiment, accommodating buffer layer 206 comprises two layers; a layer of strontium titanate (STO) or barium strontium titanate (BSTO) grown on the substrate 202 and a layer of LSAT grown on the layer of STO or BSTO.

After accommodating buffer layer 206 is formed, source and drain electrodes 210 and 208 as well as MIT channel layer 214 are formed using any convenient method. In one embodiment, the conductive material for source and drain electrodes 210 and 208 is deposited on accommodating buffer layer 206, followed by patterning of the metallization and then deposition of MIT channel layer 214 on the exposed surface 215. Alternatively, MIT channel layer 214 may be deposited first, followed by patterning of this layer and deposition of the conductive material for source electrode 210 and drain electrode 208.

Electrodes 210 and 208 may be manufactured using a variety of conductive materials. Suitable conductors include, for example, metals (platinum, aluminum, gold, etc.), polysilicon, and conductive oxides. In one embodiment, electrodes 210 and 208 comprise platinum.

MIT channel layer 214 comprises, in general, any material that undergoes a Mott metal/insulator transition at room temperature in response to an electric field. In accordance with one embodiment, MIT channel layer 214 comprises a perovskite oxide which undergoes a Mott MIT transition, for example, various cuprates such as YBa₂Cu₃O_{7-y}(YBCO), Y₁₋ₓPrₓBa₂Cu₃O_{7-y}(YPBCO, 0<x<1), La₂CuO₄, Nd₂CuO₄, and the like.

MIT channel layer 214 may be deposited using an MBE process using layer-by-layer deposition of the constitutive elements or co-deposition of the materials using known processes. In one embodiment MIT channel layer 214 comprises a cuprate deposited. at about 400-800° C. and a 1E-8 to 1E-5 mBar oxygen partial pressure. A plasma process may be used to enhance oxidation of the Cu.

The thickness of MIT channel layer 214 may be selected in accordance with the required design parameters, but in the illustrated embodiment would typically range from about 5-100 nm, preferably about 10-40 nm.

LSAT has good high frequency properties (loss tangent of 0.0002 at 77 K and 8.8 GHz) and it does not interact significantly with YBCO. In addition, unlike LAO, LSAT has no phase transformation below the melting point and therefore does not twin, and it offers much closer lattice match (0.3%) for YBCO, thereby avoiding significant stress and allowing superior crystal quality. Moreover, LSAT's effective lattice mismatching at a 45 degree rotation with reference to a [001] silicon substrate is only 0.5%. Finally, LSAT has only 1% lattice mismatching to STO or BSTO. This excellent lattice matching prevents dislocations and provides a very high quality monocrystalline structure of the YBCO or YPBCO.

After MIT channel layer 214 and electrodes 210, 208 have been formed, gate insulator 212 is deposited. In one embodiment, gate insulator 212 comprises a high-k dielectric material such as BSTO, BTO, or STO formed under growth conditions similar to those described above in connection layer 206. The thickness of gate insulator 212 may be selected in accordance with design parameters. In one embodiment, gate insulator 212 is approximately 20-400 nm in thickness.After the preceding steps, gate insulator 212 is patterned and etched to form vias in which source contact 216 and drain contact 218 are formed. After a suitable planarization step, gate electrode 220 is formed on gate insulator 212. Gate electrode 220 is preferably formed above and aligned with MIT channel layer 214.

FIGS. 21-24 show examples of high temperature superconducting devices that benefit by the use of LSAT under the YBCO or YPBCO layer.

Referring to FIG. 21, a cross section diagram of a superconducting microstrip transmission line structure 2100 is shown, in accordance with one embodiment of the present invention. A layer of LSAT 2120 is grown over a monocrystalline silicon substrate 2105, with an amorphous layer 2110 grown between the silicon substrate 2105 and the LSAT layer 2120, or between the silicon substrate 2105 and an optional layer of STO or BSTO 2115 in the manner described above for the Mott transistor 200. A layer of YBCO or YPBCO is grown on the LSAT layer 2120, providing a superconducting ground plane 2125. A second layer of LSAT 2130 is grown over the superconducting ground plane 2125, and a second layer of YBCO or YPBCO is grown on the second layer of LSAT 2130 in a desired transmission line pattern. Because the lattice of the YBCO or YPBCO layers 2125, 2135 is very closely matched to the adjacent LSAT layers 2120 and 2130, a high quality monocrystalline form of the YBCO or YPBCO is provided that has the benefits cited above, for the reasons given.

Referring to FIG. 22, a cross section diagram of a tunable superconducting microstrip transmission line structure 2200 is shown, in accordance with one embodiment of the present invention. The layer 2110, optional layer 2115, and layers 2120, 2125 are grown in the same manner as for the superconducting microstrip transmission line structure 2100, but a layer of strontium titanate (STO) or barium strontium titanate (BSTO) 2205 is grown over the second LSAT layer 2130 before a patterned layer of YBCO or YPBCO 2210 is formed to define a transmission line. The pattern of the patterned layer is achieved by known techniques, such as using a patterned template or etching a layer that has been formed as a continuous layer, resulting in a tunable superconductor microstrip transmission line structure 2200 having very high quality crystalline YBCO or YPBCO for the reasons given above.

Referring to FIG. 23, a cross section diagram of a superconducting coplanar waveguide structure 2300 is shown, in accordance with one embodiment of the present invention. The layer 2110, optional layer 2115, and layer 2120 are grown in the same manner as for the superconducting microstrip transmission line structure 2100. Strips of YBCO or YPBCO material that form ground lines 2305, 2310 and a strip of YBCO or YPBCO that forms a center conductor 2315 are grown over the LSAT layer 2120 in a suitable pattern, or the YBCO or YPBCO is grown as a continuous layer and then patterned by a known technique, such as etching, resulting in a functional superconducting coplanar waveguide device having very high quality crystalline YBCO or YPBCO for the reasons given above.

Referring to FIG. 24, a cross section diagram of a Josephson junction structure 2400 is shown, in accordance with one embodiment of the present invention. The layer 2110, optional layer 2115, and layer 2120 are grown in the same manner as for the superconducting microstrip transmission line structure 2100. Two patterned layers of YBCO or YPBCO material 2405, 2415 are formed with a layer of LSAT material 2410 between them, forming a Josephson junction. Suitable other aspects of a functional electronic structure are formed, such as electrodes, resulting in a Josephson junction device having very high quality crystalline YBCO or YPBCO for the reasons given above.

It will be appreciated that by using the techniques described herein with reference to FIGS. 1-19, a pattern of compound semiconductor material can be grown co-laterally with a pattern of YBCO or YPBCO to form a patterned layer from which an integrated circuit that includes any combination of the electronic devices described with reference to FIGS. 15-24. Alternatively, compound semiconductor materials can be grown on LSAT and STO layers that are grown over patterned YBCO and/or YPBCO layers, thereby forming an integrated circuit structure that can include any combination of electronic devices described herein. Such integrated circuit structures can be advantageously used in a wide variety of electronic equipment where high performance electronic devices are needed.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is

1. A perovskite cuprate electronic device structure, comprising:
a monocrystalline silicon substrate;
a buffer layer comprising a layer of monocrystalline lanthanum strontium aluminum tantalate (LSAT) formed overlying the monocrystalline silicon substrate; and
a layer of monocrystalline perovskite cuprate formed on the layer of monocrystalline LSAT.

2. The perovskite cuprate electronic device structure according to claim 1, wherein the monocrystalline LSAT is a solid solution of 30 mole % LaAlO₃ and 70 mole % Sr₂AlTaO₆.

3. The perovskite cuprate electronic device structure according to claim 1, wherein the monocrystalline perovskite cuprate is one of YBa₂Cu₃O_{7-y}(YBCO) and Y₁₋ₓPrₓBa₂Cu₃O_{7-y}(YPBCO, 0<x<1).

4. The perovskite cuprate electronic device structure according to claim 1, further comprising an amorphous oxide interface layer formed at an interface between the monocrystalline silicon substrate and the buffer layer.

5. The perovskite cuprate electronic device structure according to claim 4, wherein the amorphous oxide interface layer is formed at least partially during formation of the buffer layer by oxidation of an adjacent surface of the monocrystalline silicon substrate.

6. The perovskite cuprate electronic device structure according to claim 1, wherein the buffer layer further comprises a layer of one of strontium titanate or barium strontium titanate formed between the monocrystalline silicon substrate and the layer of monocrystalline LSAT.

7. The perovskite cuprate electronic device structure according to claim 1, further comprising a monocrystalline compound semiconductor layer formed on one of the buffer layer and the monocrystalline perovskite cuprate layer.

8. The perovskite cuprate electronic device structure according to claim 1, comprising at least one of a Mott transistor, a superconducting microstrip transmission line, a tunable superconducting microstrip transmission line, a superconducting coplanar waveguide, and a Josephson junction.

9. An integrated circuit comprising the electronic device structure according to claim 1.

10. An electronic equipment comprising the integrated circuit according to claim 9.

11. A process for fabricating a perovskite cuprate electronic device structure comprising:
depositing a buffer layer comprising monocrystalline lanthanum strontium aluminum tantalate (LSAT) overlying a monocrystalline silicon substrate;
forming an amorphous oxide interface layer containing at least silicon and oxygen at an interface between the buffer layer and the monocrystalline silicon substrate; and
epitaxially forming a layer of monocrystalline perovskite cuprate on the monocrystalline LSAT.

12. The process for fabricating a perovskite cuprate electronic device structure according to claim 11, wherein the monocrystalline LSAT is a solid solution of 30 mole % LaAlO₃ and 70 mole % Sr₂AlTaO₆.

13. The process for fabricating a perovskite cuprate electronic device structure according to claim 11, wherein the monocrystalline perovskite cuprate is one of YBa₂Cu₃O_{7-y}(YBCO) and Y₁₋ₓPrₓBa₂Cu₃O_{7-y}(YPBCO, 0<x<1).

14. The process for fabricating a perovskite cuprate electronic device structure according to claim 11, wherein the amorphous oxide interface layer is formed at least partially during the formation of the buffer layer by oxidation of an adjacent surface of the monocrystalline silicon substrate.

15. The process for fabricating a perovskite cuprate electronic device structure according to claim 11, wherein forming a buffer layer comprises forming of one of strontium titanate or barium strontium titanate between the monocrystalline silicon substrate and the monocrystalline LSAT.

16. The process for fabricating a perovskite cuprate electronic device structure according to claim 11, further comprising forming a monocrystalline compound semiconductor layer on one of the buffer layer and the monocrystalline perovskite cuprate layer.

17. The process for fabricating a perovskite cuprate electronic device structure according to claim 11, further comprising forming at least one of a Mott transistor, a superconducting microstrip transmission line, a tunable superconducting microstrip transmission line, a superconducting coplanar waveguide, and a Josephson junction.
